(19) United States
(12) Patent Application Publication
(10) Pub. No.: US 2017/0213948 A1
(43) Pub. Date: Jul. 27, 2017

(54) POWER GENERATOR FOR VEHICLE

(71) Applicant: TOYOTA JIDOSHA KABUSHIKI KAISHA, Toyota-shi (JP)

(72) Inventor: Kazuhiro SUGIMOTO, Susono-shi, Shizuoka-ken (JP)

(73) Assignee: TOYOTA JIDOSHA KABUSHIKI KAISHA, Toyota-shi, Aichi-ken (JP)

(21) Appl. No.: 15/367,648

(22) Filed: Dec. 2, 2016

(30) Foreign Application Priority Data
Jan. 25, 2016 (JP) 2016-011643

(51) Int. Cl. H01L 35/30; H02J 7/00; H01L 35/32; F01N 5/02

(52) U.S. Cl. CPC H01L 35/30; F01N 5/025; H02J 7/007; H01L 35/32

(57) ABSTRACT

A power generator for a vehicle equipped with a heat generating apparatus comprises a thermoelectric transducing module, a load apparatus, a current regulator and a control unit. The thermoelectric transducing module is placed on a part where exhaust heat generated from the heat generating apparatus is transmitted, and comprises a semiconductor single crystal that has an n-type semiconductor part, a p-type semiconductor part and an intrinsic semiconductor part located therebetween, the intrinsic semiconductor part having a narrower band gap than those of the n-type semiconductor part and the p-type semiconductor part. The load apparatus composes an electric circuit in cooperation with the thermoelectric transducing module. The current regulator is installed in the electric circuit and varies an electric current that is applied to the electric circuit from the thermoelectric transducing module. The control unit operates the current regulator to control electric power generated by the thermoelectric transducing module.

### CROSS-REFERENCE TO RELATED APPLICATION

This application is based on and claims the benefit of Japanese Patent Application No. 2016-011643, filed on Jan. 25, 2016, which is incorporated by reference herein in its entirety.

### BACKGROUND

Field of the Disclosure

The present disclosure relates to a power generator for a vehicle.

Background Art

As disclosed in JP2004-011512A and JP2015-140806A, a thermoelectric transducer that transduces heat into electric power using Seebeck effect is well-known. This thermoelectric transducer cannot generate electric power when there is not a temperature difference between both ends thereof. Therefore, this thermoelectric transducer requires a condition to ensure a temperature difference between the both ends. Also, there is a problem that, at power generation, escape of heat occurs from a hot end of the thermoelectric transducer to a cold end thereof.

Thus, a semiconductor single crystal disclosed in WO2015/125823A1 has attracted attention. This semiconductor single crystal has an n-type semiconductor part, a p-type semiconductor part and an intrinsic semiconductor part located between the n-type semiconductor part and the p-type semiconductor part. The intrinsic semiconductor part has a narrower band gap than band gaps of the n-type semiconductor part and the p-type semiconductor part.

This semiconductor single crystal has a remarkable feature to transduce heat into electric power in a uniform temperature field. That is, this semiconductor single crystal does not require a temperature difference between both ends thereof to generate electric power. Thus, by using this semiconductor single crystal as a thermoelectric transducer, a problem on the thermoelectric transducer utilizing Seebeck effect is solved.

### SUMMARY OF THE DISCLOSURE

As a preferred candidate of an application of the thermoelectric transducer using the semiconductor single crystal disclosed in WO2015/125823A1, a power generator for a vehicle is exemplified. The vehicle is equipped with a heat generating apparatus that generates heat during operation, for example, an internal combustion engine or electric motor as a power unit, or a fuel cell as a power-supply unit. An amount of generated heat differs according to the kind of the heat generating apparatus. However, exhaust heat, which is heat exhausted to the system outside, is inevitably generated. It is considered that energy efficiency of the vehicle can be further raised by producing electric power with the exhaust heat by using the above thermoelectric transducer.

However, the exhaust heat may be utilized in another apparatus installed in the vehicle. For example, if the heat generating apparatus is an internal combustion engine, a catalyst placed on an exhaust passage corresponds to an exhaust heat utilizing apparatus, and also a warm-up system using coolant or oil corresponds to the exhaust heat utilizing apparatus. Also, if the heat generating apparatus is an internal combustion engine or fuel cell, an air conditioning system to use exhaust heat for heating a vehicle compartment corresponds to the exhaust heat utilizing apparatus. When the generation of electric power by the thermoelectric transducer is performed while operating the exhaust heat utilizing apparatus, an amount of heat required to secure the performance of the exhaust heat utilizing apparatus may not be supplied to the exhaust heat utilizing apparatus. The electric power generated by the thermoelectric transducer can be utilized by an electric component installed in the vehicle. However, when the thermoelectric transducer generates electric power in the course of nature, excessive electric power may be generated, so that excessive electric current may flow into the electric component.

Thus, when the semiconductor single crystal disclosed in WO2015/125823A1 is used as the thermoelectric transducer for the vehicle, it is required to suitably control the generation of electric power without making the thermoelectric transducer generate electric power in the course of nature. In the case of the conventional thermoelectric transducer utilizing Seebeck effect, generated electric power can be controlled by adjusting a temperature difference between both ends thereof. However, in the case of the thermoelectric transducer capable of generating electric power without a temperature difference, a conventional control method cannot be adopted.

The present disclosure has been made in view of the above described problems, and an object of the present disclosure is to utilize a thermoelectric transducer capable of generating electric power without a temperature difference for the generation of electric power by using exhaust heat of a vehicle, and to suitably control the generation of electric power without making the thermoelectric transducer generate electric power in the course of nature. Here, “the thermoelectric transducer capable of generating electric power without the temperature difference” means a semiconductor single crystal that has an n-type semiconductor part, a p-type semiconductor part and an intrinsic semiconductor part located between the n-type semiconductor part and the p-type semiconductor part, the intrinsic semiconductor part having a narrower band gap than band gaps of the n-type semiconductor part and the p-type semiconductor part.

A power generator according to the present disclosure is a power generator that is applied to a vehicle equipped with a heat generating apparatus that generates heat during operation. The power generator according to the present disclosure comprises as follows.

The power generator according to the present disclosure comprises a thermoelectric transducing module placed on a part where exhaust heat generated from the heat generating apparatus is transmitted. This thermoelectric transducing module comprises a semiconductor single crystal disclosed in WO2015/125823A1. The semiconductor single crystal is a semiconductor single crystal that has an n-type semiconductor part, a p-type semiconductor part and an intrinsic semiconductor part located between the n-type semiconductor part and the p-type semiconductor part, the intrinsic semiconductor part having a narrower band gap than band gaps of the n-type semiconductor part and the p-type semiconductor part. Note that the thermoelectric transducing module as used herein means an assembly of the semiconductor single crystal and parts (e.g., an electrode) to functionalize the semiconductor single crystal as the thermoelectric transducer.

The power generator according to the present disclosure comprises a load apparatus composing an electric circuit in cooperation with the thermoelectric transducing module. Furthermore, the power generator according to the present disclosure comprises a current regulator that is installed in the electric circuit and varies an electric current that is applied to the electric circuit from the thermoelectric transducing module, and a control unit that operates the current regulator to control the electric power generated by the thermoelectric transducing module. If the current regulator is operated by the control unit, the electric current that is applied to the electric circuit from the thermoelectric transducing module varies according to a manipulated variable of the current regulator, and thereby the electric power generated by the thermoelectric transducing module varies. That is, the electric power generated by the thermoelectric transducing module is controlled actively by the control unit operating the current regulator.

If the power generator according to the present disclosure is applied to a vehicle that has an exhaust heat utilizing apparatus, the control unit may control the electric power generated by the thermoelectric transducing module so as to transduce into electric power at least a part of surplus exhaust heat exceeding an exhaust heat amount required by the exhaust heat utilizing apparatus. That is, the control unit may perform the generation of electric power by the thermoelectric transducing module using the surplus exhaust heat while securing the exhaust heat amount required by the exhaust heat utilizing apparatus. By such a control being executed, the influence of the generation of electric power by the thermoelectric transducing module on the performance of the exhaust heat utilizing apparatus is suppressed.

If an exhaust heat recovery fluid that recovers exhaust heat of the heat generating apparatus flows through a fluid passage and the exhaust heat utilizing apparatus is made to receive an exhaust heat supply from the exhaust heat recovery fluid flowing through the fluid passage, the thermoelectric transducing module may be placed upstream of the exhaust heat utilizing apparatus on the fluid passage. In this application, the meaning of “to place the thermoelectric transducing module on the fluid passage” includes “to place the thermoelectric transducing module inside the fluid passage” and “to place the thermoelectric transducing module outside the fluid passage and make the thermoelectric transducing module contact an outer surface of the fluid passage”. When the exhaust heat utilizing apparatus and thermoelectric transducing module are placed in this way, the control unit may control the electric power generated by the thermoelectric transducing module according to a temperature of the exhaust heat recovery fluid flowing through the fluid passage or a temperature of the exhaust heat utilizing apparatus. The temperature of the exhaust heat recovery fluid relates to an amount of heat transferred by the exhaust heat recovery fluid. Therefore, the generation of electric power is suitably controlled so as to secure the exhaust heat amount required by the exhaust heat utilizing apparatus, by controlling the thermoelectric transducing module according to the temperature of the exhaust heat recovery fluid. Also, the temperature of the exhaust heat utilizing apparatus relates to an amount of heat given to the exhaust heat utilizing apparatus. Therefore, the generation of electric power is suitably controlled so as to secure the exhaust heat amount required by the exhaust heat utilizing apparatus, by controlling the thermoelectric transducing module according to the temperature of the exhaust heat utilizing apparatus.

More specifically, the control unit may control the electric power generated by the thermoelectric transducing module so that, when a temperature of the exhaust heat recovery fluid flowing through the fluid passage is low, an amount of heat absorbed by the thermoelectric transducing module decreases in comparison with a case that the temperature of the exhaust heat recovery fluid flowing through the fluid passage is high. Furthermore, the control unit may stop the generation of electric power by the thermoelectric transducing module when the temperature of the exhaust heat recovery fluid flowing through the fluid passage is equal to or lower than a predetermined temperature. When the temperature of the exhaust heat recovery fluid flowing through the fluid passage is low, the amount of heat given to the exhaust heat utilizing apparatus is small in comparison with the case that the temperature of the exhaust heat recovery fluid flowing through the fluid passage is high. By reducing the amount of heat absorbed by the thermoelectric transducing module, the exhaust heat amount required by the exhaust heat utilizing apparatus is secured even when the amount of heat transferred by the exhaust heat recovery fluid is small.

Also, the control unit may control the electric power generated by the thermoelectric transducing module so that, when a temperature of the exhaust heat utilizing apparatus is low, an amount of heat absorbed by the thermoelectric transducing module decreases in comparison with a case that the temperature of the exhaust heat utilizing apparatus is high. Furthermore, the control unit may stop the generation of electric power by the thermoelectric transducing module when the temperature of the exhaust heat utilizing apparatus is equal to or lower than a predetermined temperature. When the temperature of the exhaust heat utilizing apparatus is low, the amount of heat given to the exhaust heat utilizing apparatus is small in comparison with the case that the temperature of the exhaust heat utilizing apparatus is high. By reducing the amount of heat absorbed by the thermoelectric transducing module, the amount of heat given to the exhaust heat utilizing apparatus increases.

The control unit may vary a manipulated variable of the current regulator according to a temperature of the thermoelectric transducing module. An electromotive voltage of the thermoelectric transducing module varies depending on the temperature thereof. Thus, the generation of electric power is more suitably controlled by making an electric current vary according to the temperature.

The control unit may vary a manipulated variable of the current regulator depending on an operating state of the load apparatus. A resistance value of the electric circuit varies depending on the operating state of the load apparatus. Thus, the generation electric power is more suitably controlled by making an electric current vary depending on the operating state of the load apparatus.

An example of the heat generating apparatus is an internal combustion engine. A catalyst is placed on an exhaust passage where an exhaust gas from the internal combustion engine flows. The thermoelectric transducing module may be placed upstream of the catalyst on the exhaust passage. In this case, the control unit may control the electric power generated by the thermoelectric transducing module so that, when a temperature of the catalyst is low or is estimated to be low, an amount of heat absorbed by the thermoelectric transducing module decreases in comparison with a case that the temperature of the catalyst is high or is estimated to be high. According to this, an amount of heat supplied to the catalyst is adjusted according to the temperature of the catalyst. Thus, the influence of the generation of electric power by the thermoelectric transducing module on the purification performance of the catalyst is suppressed.

The power generator according to the present disclosure may further comprise a battery connected to the electric circuit. The energy efficiency of the vehicle is further raised by storing the electric power generated by the thermoelectric conversion module in the battery. In this case, the control unit may control the electric power generated by the thermoelectric transducing module based on a state of charge of the battery. By doing so, the generation of electric power can be suitably controlled so as to suppress overcharge and over-discharge of the battery.

As described above, the power generator according to the present disclosure makes the control unit operate the current regulator and thereby can actively control the electric power generated by the thermoelectric transducing module, without making the thermoelectric transducing module generate electric power in the course of nature.

### BRIEF DESCRIPTION OF DRAWINGS

FIG. 1 schematically shows a structure of a thermoelectric transducer (semiconductor single crystal) of an embodiment of the present disclosure;

FIG. 2A conceptually shows a state of thermal excitation when the thermoelectric transducer is heated to a predetermined temperature;

FIG. 2B conceptually shows movements of an electron and a hole when the thermoelectric transducer is heated to a predetermined temperature;

FIG. 3 schematically shows a structure of a thermoelectric transducing module of an embodiment of the present disclosure;

FIG. 4 shows a relation between a temperature and an electromotive voltage of the thermoelectric transducer;

FIG. 5 shows a relation between a module temperature and an electromotive voltage of the thermoelectric transducing module;

FIG. 6 shows a load on the thermoelectric transducing module that varies with time;

FIG. 7 conceptually shows a relation between a load on the thermoelectric transducing module and an electric power generated by the thermoelectric transducing module;

FIG. 8 schematically shows a first application of the thermoelectric transducing module to an internal combustion engine;

FIG. 9 schematically shows a second application of the thermoelectric transducing module to the internal combustion engine;

FIG. 10 schematically shows a third application of the thermoelectric transducing module to the internal combustion engine;

FIG. 11 schematically shows a structure of a power generator of a first embodiment of the present disclosure;

FIG. 12 shows an example of a relation between a temperature Tin at an upstream side of the thermoelectric transducing module in a fluid passage and an electric power P generated by the thermoelectric transducing module;

FIG. 13 shows an example of a relation between a temperature Tin at an upstream side of the thermoelectric transducing module in the fluid passage, an electric power P generated by the thermoelectric transducing module, and a temperature Tout at a downstream side of the thermoelectric transducing module in the fluid passage;

FIG. 14 schematically shows an equivalent circuit of the power generator of the first embodiment;

FIG. 15 shows a relation between a variable resistance value and an electric power;

FIG. 16 shows an example of a relation between a temperature Tin at an upstream side of the thermoelectric transducing module in the fluid passage and an electric power P generated by the thermoelectric transducing module, which can be achieved by adjusting the variable resistance value;

FIG. 17 shows an example of a relation between a temperature Tin at an upstream side of the thermoelectric transducing module in the fluid passage, an electric power P generated by the thermoelectric transducing module, and a temperature Tout at a downstream side of the thermoelectric transducing module in the fluid passage, which can be achieved by adjusting the variable resistance value;

FIG. 18 shows a flowchart indicating a program for heat recovery control by the power generator of the first embodiment;

FIG. 19 shows an image of a map used for determining a target electric power by the program for the heat recovery control of the first embodiment;

FIG. 20 schematically shows a structure of a power generator of a second embodiment of the present disclosure;

FIG. 21 shows a flowchart indicating a program for heat recovery control by the power generator of the second embodiment;

FIG. 22 shows an image of a map used for determining a target electric power by the program for the heat recovery control of the second embodiment;

FIG. 23 shows a structure of an application example of the power generator of the first embodiment; and

FIG. 24 shows a flowchart indicating a program for heat recovery control by the power generator shown in FIG. 23.

### DETAILED DESCRIPTION

Embodiments of the present disclosure are described hereunder with reference to the accompanying drawings. However, it is to be understood that even when the number, quantity, amount, range or other numerical attribute of an element is mentioned in the following description of the embodiments, the present disclosure is not limited to the mentioned numerical attribute unless it is expressly stated or theoretically defined. Further, structures or steps or the like described in conjunction with the following embodiments are not necessarily essential to the present disclosure unless expressly stated or theoretically defined.

### [Structure of Thermoelectric Transducer]

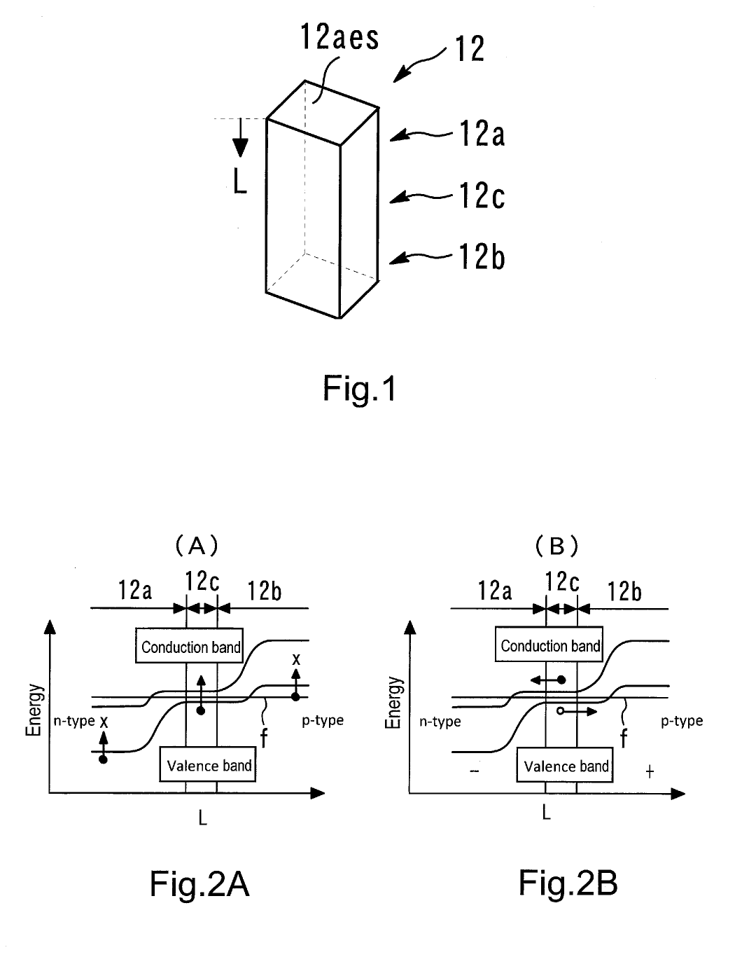

FIG. 1 schematically shows a structure of a thermoelectric transducer 12 of an embodiment of the present disclosure. In the example shown in FIG. 1, the thermoelectric transducer 12 has the shape of a prism. The thermoelectric transducer 12 has an n-type semiconductor part 12a at one end and a p-type semiconductor part 12b at the other end. The thermoelectric transducer 12 further has an intrinsic semiconductor part 12c between the n-type semiconductor part 12a and the p-type semiconductor part 12b.

FIGS. 2A and 2B conceptually shows statuses of the band gap energy of the thermoelectric transducer 12 shown in FIG. 1. In FIGS. 2A and 2B, the vertical axes indicate the energy of an electron, and the horizontal axes indicate the distance L (see FIG. 1) from an end face 12aes of the thermoelectric transducer 12 on the side of the n-type semiconductor part 12a.

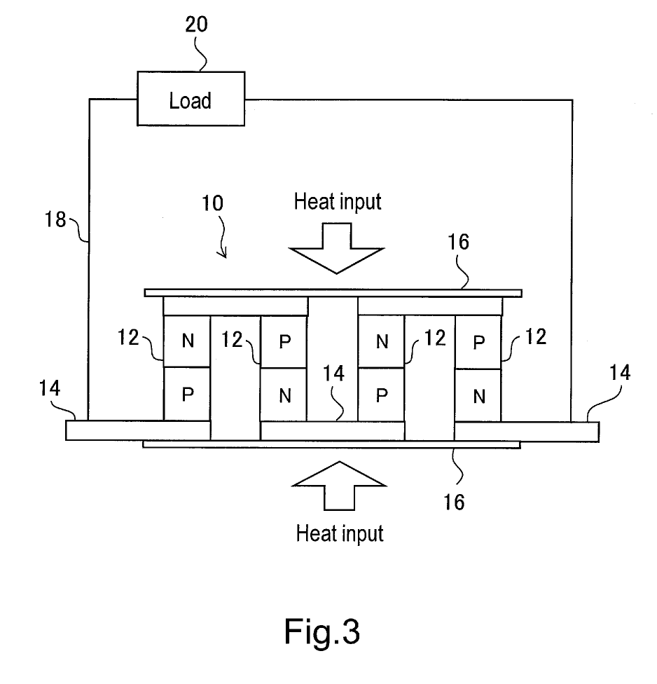

As shown in FIGS. 2A and 2B, in the n-type semiconductor part 12a, the Fermi level f is in the conduction band, and in the p-type semiconductor part 12b, the Fermi level f is in the valence band. In the intrinsic semiconductor part 12c, the Fermi level f is at the middle of the forbidden band existing between the conduction band and the valence band. The band gap energy corresponds to the difference in energy between the uppermost part of the valence band and the lowermost part of the conduction band. As can be seen from these figures, the band gap energy of the intrinsic semiconductor part 12c of the thermoelectric transducer 12 is lower than the band gap energies of the n-type semiconductor part 12a and the p-type semiconductor part 12b. Note that the length ratio between the n-type semiconductor part 12a, the p-type semiconductor part 12b and the intrinsic semiconductor part 12c shown in FIGS. 3A and 3B is just an example, and the ratio can vary depending on how the thermoelectric transducer (semiconductor single crystal) 12 is formed. The band gap energy of the n-type semiconductor part 12a, the p-type semiconductor part 12b and the intrinsic semiconductor part 12c can be measured in inverse photoelectron spectroscopy, for example.

The thermoelectric transducer (semiconductor single crystal) 12 having the characteristics described above (that is, the band gap energy of the intrinsic semiconductor part 12c is lower than the band gap energies of the n-type semiconductor part 12a and the p-type semiconductor part 12b) can be made of a clathrate compound (inclusion compound), for example. As an example of the clathrate compound, a silicon clathrate Ba8Au8Si38 may be used.

The thermoelectric transducer 12 according to the present embodiment can be manufactured in any method, as far as the method can produce the thermoelectric transducer 12 having the characteristics described above. If the thermoelectric transducer 12 is made of, for example, the silicon clathrate Ba8Au8Si38, the manufacturing method described in detail in WO2015/125823A1 can be used, for example. The manufacturing method can be summarized as follows. That is, Ba powder, Au powder and Si powder are weighed in the ratio (molar ratio) of 8:8:38. The weighed powders are melted together by arc melting. The melt is then cooled to form an ingot of the silicon clathrate Ba8Au8Si38. The ingot of the silicon clathrate Ba8Au8Si38 prepared in this way is crushed into grains. The grains of the silicon clathrate Ba8Au8Si38 are melted in a crucible in the Czochralski method, thereby forming a single crystal of the silicon clathrate Ba8Au8Si38. The thermoelectric transducer 12 shown in FIG. 1 is provided by cutting the single crystal of the silicon clathrate Ba8Au8Si38 prepared in this way into the shape of a prism (more specifically, the shape of a rectangular parallelepiped). The shape of the thermoelectric transducer is not limited to the rectangular parallelepiped, and the thermoelectric transducer may have any shape provided by cutting the single crystal into a desired shape, such as a cube or a column.

### [Principle of Power Generation]

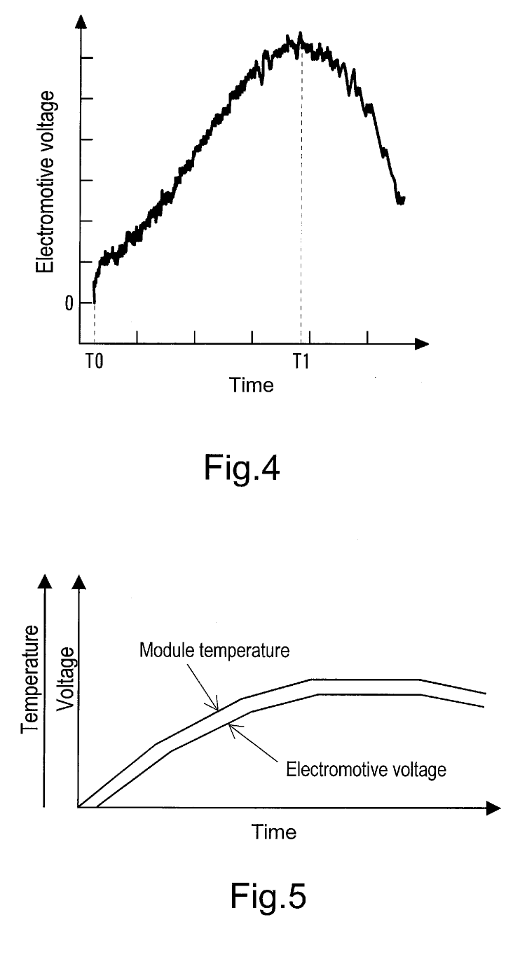

FIG. 2A conceptually shows a status of thermal excitation of the thermoelectric transducer 12 when the thermoelectric transducer 12 is heated to a predetermined temperature. If the thermoelectric transducer 12 is heated to a temperature T0 (see FIG. 4 described later) or higher, electrons (shown by black dots) in the valence band are thermally excited into the conduction band, as shown in FIG. 2A. More specifically, if heat is supplied and energy exceeding the band gap energy is thereby supplied to an electron located in an uppermost part of the valence band, the electron is excited into the conduction band. In the process where the temperature of the thermoelectric transducer 12 increases, a condition can occur in which such thermal excitation of electrons occurs only in the intrinsic semiconductor part 12c, which has a relatively low band gap energy. FIG. 2A shows a status of the thermoelectric transducer 12 in which the thermoelectric transducer 12 is heated to a predetermined temperature (such as the temperature T0) that can allow such a condition to occur. In this status, no electrons are thermally excited in the n-type semiconductor part 12a and the p-type semiconductor part 12b, which have a relatively higher band gap energy.

FIG. 2B conceptually shows movements of an electron (shown by the black dot) and a hole (shown by a white dot) when the thermoelectric transducer 12 is heated to the predetermined temperature described above. As shown in FIG. 2B, electrons excited into the conduction band move toward a part of lower energy, that is, toward the n-type semiconductor part 12a. On the other hand, holes formed in the valence band as a result of the electrons being excited move toward a part of higher energy, that is, toward the p-type semiconductor part 12b. The carriers are unevenly distributed in this way, so that the n-type semiconductor part 12a is negatively charged, and the p-type semiconductor part 12b is positively charged, and therefore, an electromotive force occurs between the n-type semiconductor part 12a and the p-type semiconductor part 12b. Thus, the thermoelectric transducer 12 can generate power even if there is no temperature difference between the n-type semiconductor part 12a and the p-type semiconductor part 12b. This principle of power generation differs from the Seebeck effect, which produces an electromotive force based on a temperature difference.

### [Structure of Thermoelectric Transducing Module]

The thermoelectric transducer 12 is not used alone in the vehicle. The thermoelectric transducer 12 constitutes a thermoelectric transducing module with other parts and is used in the form of the thermoelectric transducing module. FIG. 3 schematically shows a structure of the thermoelectric transducing module 10 of the present embodiment. The thermoelectric transducing module 10 of the present embodiment comprises a plurality of thermoelectric transducers 12. “P”, “N” in FIG. 3 show the p-type semiconductor part and the n-type semiconductor part of the thermoelectric transducer 12, respectively. The intrinsic semiconductor part not shown is located therebetween. Each thermoelectric transducer 12 is sandwiched from both sides by electrodes 14 and is serially-connected through the electrode 14. The series body in which the thermoelectric transducer 12 and the electrode 14 are serially-connected is put in a casing 16. The casing 16 has high thermal conductivity. Also, the casing 16 insulates the inside from the outside. In the present embodiment, the thermoelectric transducing module 10 comprises the thermoelectric transducers 12, the electrodes 14 and the casing 16 containing them. However, depending on the environment in which the thermoelectric transducing module 10 is installed, the casing 16 can be omitted. Conducting wires 18 to take electric power out of the thermoelectric transducing module 10 is pulled out from electrodes 14 of the both ends of the series body. The conducting wires 18 are connected to an external load 20 and thereby an electric circuit is made. When the thermoelectric transducing module 10 receives heat input, the generation of electric power by the thermoelectric transducing module 10 starts. As described repeatedly, the temperature difference is not required for the generation of electric power by the thermoelectric transducer 12. Therefore, the thermoelectric transducing module 10 receives heat input and generates electric power even in the environment without the temperature difference.

Note that, in FIG. 3, the thermoelectric transducing module 10 comprises four thermoelectric transducers 12, but this is only an example. More thermoelectric transducers 12 may be serially-connected. If the thermoelectric transducer 12 has enough power generation capability, the thermoelectric transducing module 10 may comprise a single thermoelectric transducer 12. That is, the number of the thermoelectric transducers 12 composing the thermoelectric transducing module 10 is determined based on the electric power that the thermoelectric transducing module 10 is required to generate and the electric power that one thermoelectric transducer 12 can generate. Also, in FIG. 3, the thermoelectric transducer 12 is illustrated as a stick shape, but the thermoelectric transducer 12 may have a thin board shape. The board-shaped thermoelectric transducer 12 can be laminated in one direction.

### [Generation Characteristic of Thermoelectric Transducing Module]

Next, generation characteristic of the thermoelectric transducing module 10 will be described. FIG. 4 shows an example of a relation between an electromotive voltage and a temperature of the thermoelectric transducer 12 in the thermoelectric transducing module 10. Herein, the electromotive voltage of the thermoelectric transducer 12 means a potential difference between one end on the side of the p-type semiconductor part 12b functioning as an anode and the other end on the side of the n-type semiconductor part 12a functioning as a cathode. More specifically, the relation shown in FIG. 4 represents a temperature characteristic of the electromotive voltage appearing when the thermoelectric transducer 12 is heated in a manner that does not produce a temperature difference between the n-type semiconductor part 12a and the p-type semiconductor part 12b. The electromotive voltage is produced when the thermoelectric transducer 12 is placed in an environment where the temperature is higher than a certain temperature. The electromotive voltage increases as the temperature of the thermoelectric transducer 12 increases, reaches a peak value at a certain temperature, and decreases as the temperature of the thermoelectric transducer 12 becomes higher than the certain temperature. As can be seen from this relation, the electromotive voltage of the thermoelectric transducer 12 depends on the temperature.

The above described relation between the temperature and the electromotive voltage of the thermoelectric transducer 12 is applied to a relation between a module temperature and an electromotive voltage of the thermoelectric transducing module 10 (a potential difference between electrodes of both ends). FIG. 5 shows an example of a relation between the module temperature and the electromotive voltage of the thermoelectric transducing module 10. As shown in FIG. 5, the electromotive voltage varies depending on the module temperature varying with time. When the electromotive voltage varies, a variation also occurs in the electric power generated by the thermoelectric transducing module 10.

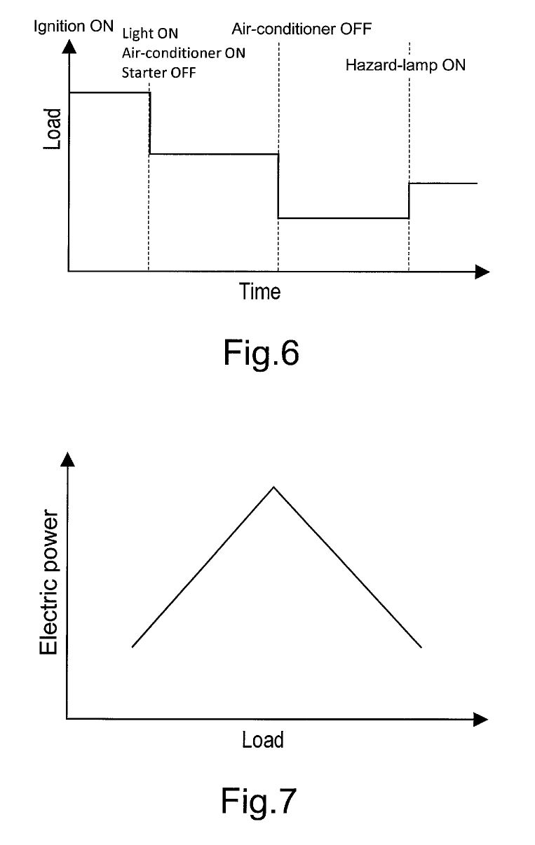

The factor varying the electric power that thermoelectric transducing module 10 generates is not only the module temperature. A load that acts on the thermoelectric transducing module 10 also influences the electric power. When the load is generated by electric components of the vehicle, the load varies consistently depending on the state of the vehicle varying with time. For example, FIG. 6 shows an example of the load varying depending on the state of the vehicle. Specifically, FIG. 6 shows the operating state of the electric components after a turn-on of the ignition of the vehicle, and shows the variation of the load depending on the operating state of the electric components. The load acting on the thermoelectric transducing module 10 varies with on/off of a starter, on/off of an air-conditioner, on/off of a light and so on.

FIG. 7 conceptually shows a relation between the load acting on the thermoelectric transducing module 10 and the electric power generated by the thermoelectric transducing module 10. The electric power that the thermoelectric transducing module 10 generates increases as the load becomes high, reaches a peak value at a certain load value, and decreases as the load becomes higher than the certain load value. When the temperature of the thermoelectric transducer 12 rises, the thermal excitation of electrons and holes occurs not only in the intrinsic semiconductor part 12c but also in the n-type semiconductor part 12a and the p-type semiconductor part 12b. It is considered that the relation shown in FIG. 7 is based on this fact. As can be seen from this relation, the electric power generated by the thermoelectric transducing module 10 varies with the magnitude of the load that acts on the thermoelectric transducing module 10. Thus, when the load that acts on the thermoelectric transducing module 10 varies as shown in FIG. 7, the electric power generated by the thermoelectric transducing module 10 also varies depending on the variation of the load.

### [Application of Thermoelectric Transducing Module]

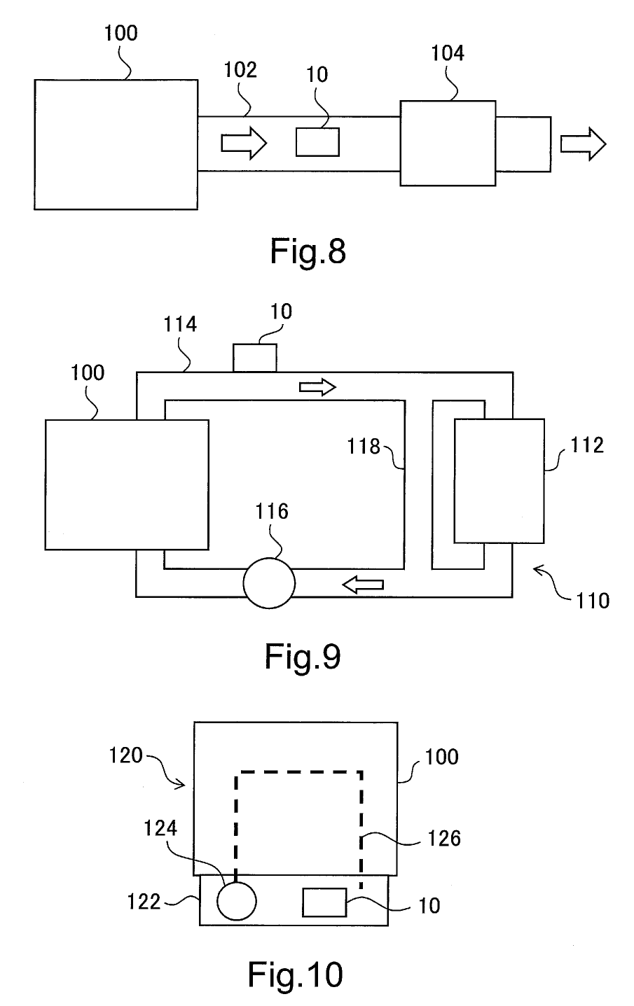

Contrary to a conventional thermoelectric transducer using the Seebeck effect, the thermoelectric transducing module 10 of the present embodiment does not need a temperature difference to generate electric power. Thus, there is less constraint on applying the thermoelectric transducing module 10 to the vehicle in comparison with the conventional thermoelectric transducer using the Seebeck effect. The thermoelectric transducing module 10 can be installed in various places of the vehicle. Each of FIG. 8 to FIG. 10 shows an application of the thermoelectric transducing module 10 when a heat generating apparatus installed in the vehicle is an internal combustion engine 100. In each of FIG. 8 to FIG. 10, a circuit and a load connected to the thermoelectric transducing module 10 are omitted.

In a first application shown in FIG. 8, the thermoelectric transducing module 10 is installed inside an exhaust passage 102 of the internal combustion engine 100. An exhaust gas is an exhaust heat recovery fluid that recovers the exhaust heat of the internal combustion engine 100. The exhaust passage 102 is a fluid passage where the exhaust gas as the exhaust heat recovery fluid flows. The heat that the exhaust gas has is given directly to the thermoelectric transducing module 10. The thermoelectric transducing module 10 transduces the heat given from the exhaust gas into electric power.

A catalyst 104 to purify the exhaust gas is placed on the exhaust passage 102. The catalyst 104 shows purification capability when being warmed-up by the heat that the exhaust gas has. That is, the catalyst 104 is an exhaust heat utilizing apparatus using the exhaust heat of the internal combustion engine 100. In an example shown in FIG. 8, the thermoelectric transducing module 10 is placed upstream of the catalyst 104. In the case of such a placement, a part of the heat that exhaust has is absorbed in the thermoelectric transducing module 10, and the remainder is supplied to the catalyst 104. Note that the thermoelectric transducing module 10 may be placed downstream of the catalyst 104.

The thermoelectric transducing module 10 may be placed on the outer surface of the exhaust passage 102 instead of the inside of the exhaust passage 102. In this case, the heat that is transferred from the inside of exhaust passage 102 to the outside by heat conduction is absorbed in the thermoelectric transducing module 10 placed on the surface, and is transduced into electric power by the thermoelectric transducing module 10. Note that there is a temperature difference between the outer surface of the exhaust passage 102 and the outside world, but this temperature difference is not necessary for the generation of electrical power by the thermoelectric transducing module 10. For this reason, the circumference of the exhaust passage 102 as well as the circumference of the exhaust passage 102 may be covered with an insulation material to suppress heat radiation from the exhaust passage 102 and the thermoelectric transducing module 10 to the outside world.

In a second application shown in FIG. 9, the thermoelectric transducing module 10 is applied to a coolant circulation system 110 of the internal combustion engine 100. The coolant circulation system 110 comprises a radiator 112, a coolant circulation passage 114 circulating a coolant between the radiator 112 and the internal combustion engine 100, a circulating pump 116, and a bypass passage 118 bypassing the radiator 112. The thermoelectric transducing module 10 is placed downstream of the internal combustion engine 100 and upstream of the radiator 112 on the coolant circulation passage 114. In an example shown in FIG. 9, the thermoelectric transducing module 10 is placed on the outer surface of the coolant circulation passage 114. The coolant is an exhaust heat recovery fluid that recovers the exhaust heat of the internal combustion engine 100. The coolant circulation passage 114 is a fluid passage where the coolant as the exhaust heat recovery fluid flows. The heat that the coolant has is given to the thermoelectric transducing module 10 through a tube wall of the coolant circulation passage 114. The thermoelectric transducing module 10 transduces the given heat into electric power.

At a cold startup of the internal combustion engine 100, the coolant circulation system 110 closes the coolant flow passage in the radiator 112 and makes the coolant pass through the bypass passages 118. Thereby, the coolant heated by the exhaust heat of the internal combustion engine 100 is returned to the internal combustion engine 100 again, and a warm-up of the internal combustion engine 100 is promoted. That is, the internal combustion engine 100 in the coolant circulation system 110 is also an exhaust heat utilizing apparatus using the exhaust heat of the internal combustion engine 100.

The thermoelectric transducing module 10 may be placed inside the coolant circulation passage 114 instead of on the outer surface of the coolant circulation passage 114. Also, the thermoelectric transducing module 10 may be placed inside the radiator 112 or placed on the surface thereof. In addition to or instead of cooling the coolant by heat exchange with the atmosphere, it may be performed to cool the coolant by heat absorption at the generation of electric power by the thermoelectric transducing module 10.

In a third application shown in FIG. 10, the thermoelectric transducing module 10 is applied to an oil circulation system 120 of the internal combustion engine 100. The oil circulation system 120 comprises an oil pan 122, an oil pump 124, and an oil circulation passage 126. In an example shown in FIG. 10, the thermoelectric transducing module 10 is placed inside the oil pan 122. The oil is an exhaust heat recovery fluid that recovers the exhaust heat of the internal combustion engine 100. The oil pan 122 and the oil circulation passage 126 compose a fluid passage where the oil as the exhaust heat recovery fluid flows. The heat that oil has is given directly to the thermoelectric transducing module 10. The thermoelectric transducing module 10 transduces the given heat into electric power.

At a cold startup of the internal combustion engine 100, a warm-up of the internal combustion engine 100 is promoted by the oil heated by the exhaust heat of the internal combustion engine 100 circulating. That is, the internal combustion engine 100 in the oil circulation system 120 is also an exhaust heat utilizing apparatus using the exhaust heat of the internal combustion engine 100.

The thermoelectric transducing module 10 may be placed on the outer surface of the oil pan 122 or on the circulation passage 126 instead of inside the oil pan 122. When the oil circulation system 120 comprises an oil cooler, the thermoelectric transducing module 10 is preferably placed upstream of the oil cooler. Also, the thermoelectric transducing module 10 may be placed on the outer surface of a cylinder block or cylinder head, or placed inside the cylinder block or cylinder head.

The thermoelectric transducing module 10 may be placed on a fuel line or an outlet of a compressor on an inlet passage. When a fuel cell is installed in the vehicle, the thermoelectric transducing module 10 may be placed on a cathode off-gas passage of the fuel cell that is a heat generating apparatus. Also, the thermoelectric transducing module 10 may be placed on any heat generating apparatus, which generates heat during operation, so as to recover exhaust heat of the heat generating apparatus. Such a heat generating apparatus includes a transmission, a battery, a brake system, and the like.

### [Structure of Power Generator of First Embodiment]

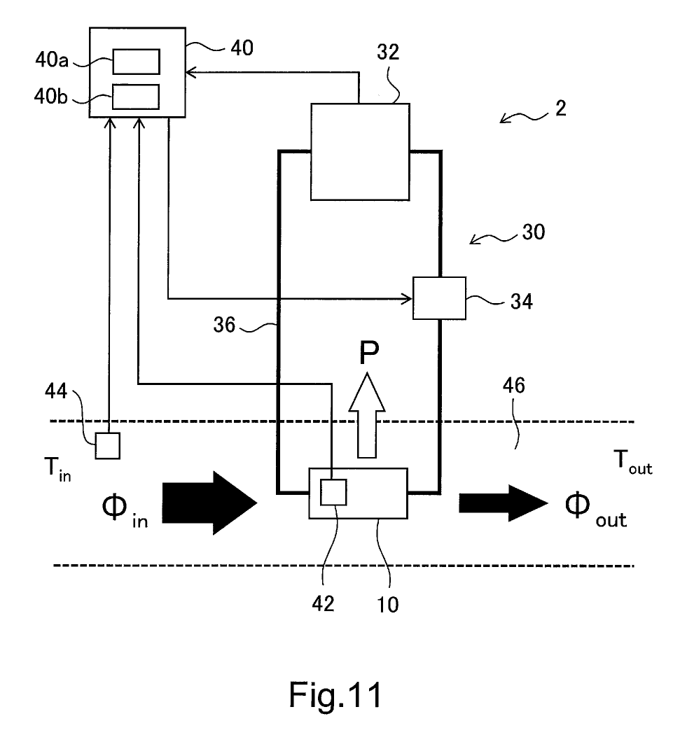

The power generator described hereinafter is a device to functionalize the thermoelectric transducing module 10. FIG. 11 shows a structure of the power generator 2 of a first embodiment. The power generator 2 of the first embodiment comprises the thermoelectric transducing module 10 placed inside the fluid passage 46 or on the outer surface of the fluid passage 46. An exhaust heat recovery fluid such as an exhaust gas or coolant flows through the fluid passage 46. The thermoelectric transducing module 10 is electrically connected to a load apparatus 32 through a conducting wire 36 and composes an electric circuit 30 together with the load apparatus 32. The load apparatus 32 is an apparatus using electric power and includes a drive motor and an electric component such as an air-conditioner or headlight.

This electric circuit 30 is further provided with a current regulator 34 comprising a variable resistance. The current regulator 34 is a device that can vary an electric current flowing through the electric circuit 30, that is, an electric current applied to the electric circuit 30 from the thermoelectric transducing module 10, by varying the resistance value of the variable resistance. Also, the current regulator 34 has a switch that turns on or turns off an electric current flowing through the electric circuit 30. In an example shown in FIG. 11, the current regulator 34 is serially-connected with the load apparatus 32. Note that the current regulator 34 may comprise, in substitution for the variable resistance, a plurality of resistances and a switch for switching the plurality of resistances.

The thermoelectric transducing module 10 is placed on the fluid passage 46, and thereby a part of the heat that the exhaust heat recovery fluid has is transduced into electric power by the thermoelectric transducing module 10. In FIG. 11, “Φin” denotes an input heat amount that is a heat amount per unit time inputted from upstream of the fluid passage 46 to an area where the thermoelectric transducing module 10 is placed, “P” denotes an electric power generated by the thermoelectric transducing module 10, and “Φout” denotes an output heat amount that is a heat amount per unit time outputted to downstream of the fluid passage 46 from the area where the thermoelectric transducing module 10 is placed. Note that the term “generated electric power” used in this Description means an electric power taken out from the thermoelectric transducing module 10. An electric power consumed by an internal resistance of the thermoelectric transducing module 10 is not included in the electric power P, that is, generated electric power. Thus, the electric power P becomes smaller than the difference between the input heat amount Φin and the output heat amount Φout. Also, in FIG. 11, “Tin” denotes a temperature at an upstream side of the thermoelectric transducing module 10 in the fluid passage 46, and “Tout” denotes a temperature at an downstream side of the thermoelectric transducing module 10 in the fluid passage 46.

The power generator 2 of the first embodiment 1 further comprises a control unit 40. The control unit 40 operates the resistance value of the variable resistance of the current regulator 34, and thereby varies the electric current value to control the electric power generated by the thermoelectric transducing module 10. Controlling the electric power generated by the thermoelectric transducing module 10 is equivalent to controlling a recovery amount of exhaust heat. Hereinafter, the control of the electric power generated by the thermoelectric transducing module 10 that is executed by the control unit 40 is referred to as a heat recovery control. The electric power generated by the thermoelectric transducing module 10 is a control variable for the heat recovery control. The resistance value of the variable resistance of the current regulator 34 is a manipulated variable for the heat recovery control. The control unit 40 is an ECU comprising at least one memory 40a and at least one processor 40b. The memory 40a stores various data including a program and map for the heat recovery control. Functions for the heat recovery control are implemented into the control unit 40 by reading the program from the memory 40a and executing it by the processor 40b.

Various sensors to acquire information associated with the heat recovery control are connected to the control unit 40 directly or through a communication network built in the vehicle. The sensors connected to the control unit 40 include two temperature sensors 42, 44. One sensor is a module temperature sensor 42 that is provided inside the thermoelectric transducing module 10 and measures a temperature of the thermoelectric transducing module 10. The other sensor is a heat source temperature sensor 44 that is placed upstream of the thermoelectric transducing module 10 on the fluid passage 46 and measures a temperature of the exhaust heat recovery fluid that is a heat source.

### [Contents of Heat Recovery Control]

The contents of the heat recovery control executed by the control unit 40 will be described in detail.

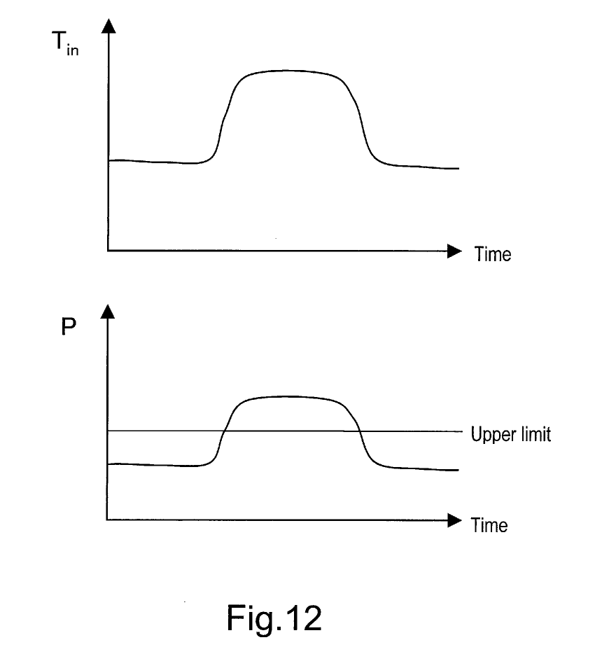

At first, as a comparative example, a problem will be described that occurs when the heat recovery control is not executed by the control unit 40, that is, when the thermoelectric transducing module 10 is made to generate electric power in the course of nature. FIG. 12 shows an example of a relation between the temperature Tin at an upstream side of the thermoelectric transducing module 10 in the fluid passage 46 and the electric power P generated by the thermoelectric transducing module 10, which is obtained when the thermoelectric transducing module 10 is made to generate electric power in the course of nature. As shown in FIG. 12, when the upstream temperature Tin of the fluid passage 46 rises, the electric power P also rises accordingly. The reason is because, as described using FIGS. 4 and 5, the electromotive voltage of the thermoelectric transducing module 10 depends on the temperature of the thermoelectric transducing module 10, and the temperature of the thermoelectric transducing module 10 follows the upstream temperature Tin of the fluid passage 46. At this time, the electric power P generated by the thermoelectric transducing module 10 is consumed by the load apparatus 32. However, if the electric power P is excessive, an excessive electric current flows in the load apparatus 32. That is, in the case of the generation of electric power in the course of nature, the electric power P may exceed an upper limit that is a predetermined permission electric power in accordance with a rise of the upstream temperature Tin of the fluid passage 46.

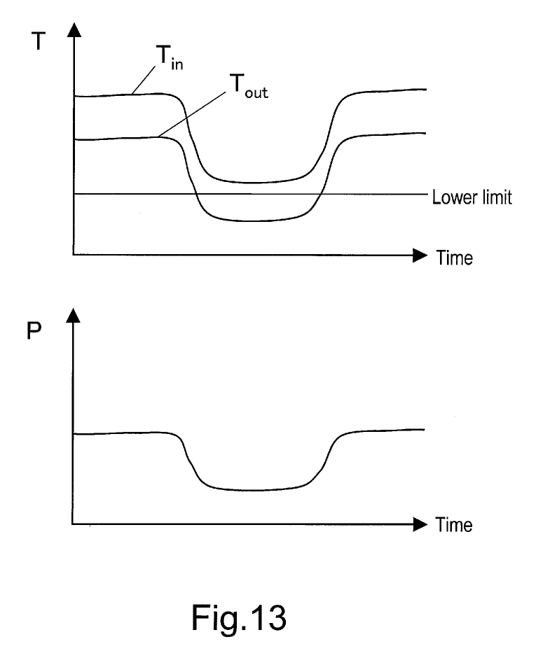

FIG. 13 shows an example of a relation between the temperature Tin at an upstream side of the thermoelectric transducing module 10 in the fluid passage 46, the electric power P generated by the thermoelectric transducing module 10, and the temperature Tout at a downstream side of the thermoelectric transducing module 10 in the fluid passage 46. The ordinate axis T of the upper graph in FIG. 13 shows the temperature. The upper graph shows time variations of the upstream temperature Tin and the downstream temperature Tout. The ordinate axis P of the lower graph in FIG. 13 shows the electric power. The lower graph shows a time variation of the electric power P generated by the thermoelectric transducing module 10. The upper graph and the lower graph have a common time axis. When the generation of electric power by the thermoelectric transducing module 10 is performed, the heat that the exhaust heat recovery fluid has is taken out as electric power P. Therefore, the downstream temperature Tout of the fluid passage 46 becomes lower than the upstream temperature Tin of the fluid passage 46. When an exhaust heat utilizing apparatus is provided downstream of the fluid passage 46, a drop in the downstream temperature Tout of the fluid passage 46 causes a deterioration in the performance of the exhaust heat utilizing apparatus. That is, in the case of the generation of electric power in the course of nature, the downstream temperature Tout of the fluid passage 46 may become lower than a lower limit temperature that causes a deterioration in the performance of the exhaust heat utilizing apparatus, and thereby the amount of heat required to secure the performance of the exhaust heat utilizing apparatus may not be supplied to the exhaust heat utilizing apparatus.

The control unit 40 actively controls the electric power generated by the thermoelectric transducing module 10 so that the above described problem does not happen. The heat recovery control by the control unit 40 is executed based on an equivalent circuit model that models an equivalent circuit of the power generator 2.

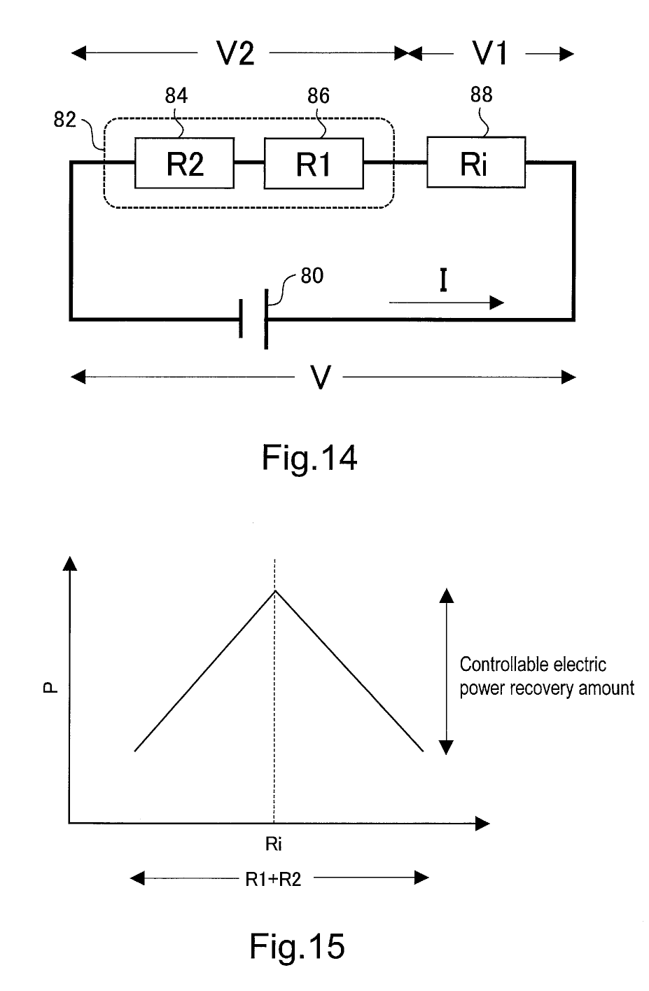

FIG. 14 schematically shows an equivalent circuit of the power generator 2. As shown in FIG. 14, the equivalent circuit model is expressed by a DC power supply 80 having a voltage value V and three resistances 84, 86, 88 serially-connected to the DC power supply 80. The voltage value V of the DC power supply 80 represents the electromotive voltage of the thermoelectric transducing module 10. The resistance 84 is a load resistance of the load apparatus 32, and R2 represents a resistance value of the load resistance. Hereinafter, this resistance value is referred to as “load resistance value R2”. The resistance 86 is a variable resistance of the current regulator 34, and R1 represents a resistance value of the variable resistance. Hereinafter, this resistance value is referred to as “variable resistance value R1”. The resistance 88 is an internal resistance of the thermoelectric transducing module 10, and Ri represents a resistance value of the internal resistance. Hereinafter, this resistance value is referred to as “internal resistance value Ri”. The resistance 84 and resistance 86 compose an external resistance 82. A total resistance value R1+R2 that is obtained by adding the load resistance value R2 to the variable resistance value R1 is a resistance value of the external resistance 82. In FIG. 14, the value of the voltage applied to the external resistance 82 is represented by V2, the value of the voltage applied to the internal resistance 88 is represented by V1, and the value of the current flowing in the circuit is represented by I.

According to the equivalent circuit model shown in FIG. 14, the electric power P that is generated by and taken out from the thermoelectric transducing module 10 is represented by following formula (1).

P=V2*I=V1*(V−V1)/Ri (1)

According to formula (1), the electric power P taken out from the thermoelectric transducing module 10 is determined by the electromotive voltage value V, applied voltage value V1 and internal resistance value Ri. When assuming that the temperature of the thermoelectric transducing module 10 is constant during a certain period of time, the electromotive voltage value V is regarded as constant during the certain period of time because the electromotive voltage value V depends on the performance of the thermoelectric transducing module 10. Also, the internal resistance value Ri is regarded as constant because the internal resistance value Ri depends on the structure of the thermoelectric transducing module 10. Therefore, the electric power P depends on the applied voltage value V1. The applied voltage value V1 is represented by following formula (2).

V1=(Ri/(R+Ri))*V=(Ri/(R1+R2+Ri))*V (2)

In formula (2), the load resistance value R2 is a given value depending on the operating state of the load apparatus 32, and the electromotive voltage value V and internal resistance value Ri are constant values as above. That is, the load resistance value R2, electromotive voltage value V and internal resistance value Ri are parameters that the control unit 40 cannot adjust arbitrarily. In contrast, the variable resistance value R1 is a parameter adjustable by the control unit 40. The applied voltage value V1 is varied by adjusting the variable resistance value R1. The electric power P depends on the applied voltage value V1 according to a relation shown in formula (1). Thus, the electric power P can be made to vary by adjusting the variable resistance value R1. FIG. 15 conceptually shows a relation between the electric power P taken out from the thermoelectric transducing module 10 and the external resistance value R1+R2. As shown in FIG. 15, the electric power P taken out from the thermoelectric transducing module 10 increases as the external resistance value R1+R2 increases. When the external resistance value R1+R2 becomes equal to the internal resistance value Ri, the electric power P reaches a peak value. As the external resistance value R1+R2 increases further, the electric power P decreases.

The control unit 40 has a program describing a formula that expresses the relation shown in FIG. 15 or a map that expresses the relation shown in FIG. 15. In the heat recovery control by the control unit 40, at first, a target value of the electric power P is determined, and then, the variable resistance value R1 is calculated based on the target value of the electric power P and the load resistance value R2 with reference to the relation shown in FIG. 15. Note that, according to the relation shown in FIG. 15, there exist two external resistance values R1+R2 giving the electric power P except the peak value. Which value of the two external resistance values R1+R2 should be selected can be determined based on a permissible current value or required current value. The control unit 40 operates the current regulator 34 so that a resistance value of the resistance 86 becomes equal to the calculated variable resistance value R1.

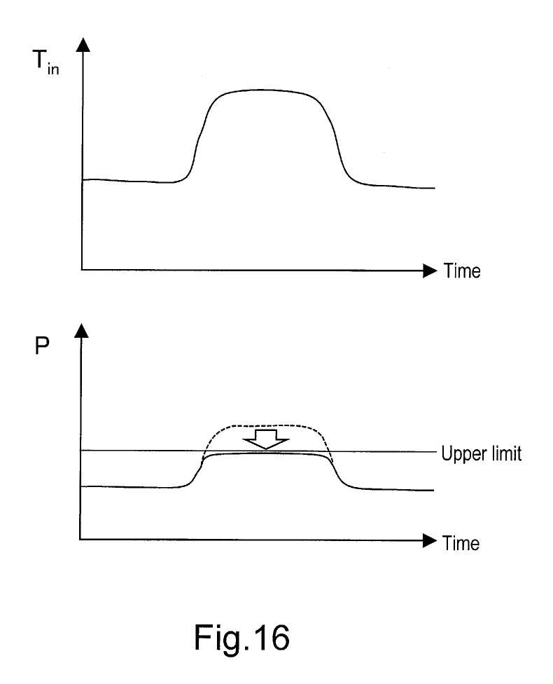

FIG. 16 shows an example of a relation between the temperature Tin at an upstream side of the thermoelectric transducing module 10 in the fluid passage 46 and the electric power P generated by the thermoelectric transducing module 10, which can be achieved by adjusting the variable resistance value. As shown in FIG. 16, when the upstream temperature Tin of the fluid passage 46 rises, the electric power P also rises accordingly. In this case, if the thermoelectric transducing module 10 is made to generate electric power in the course of nature, the electric power P may exceed an upper limit as shown by a dotted line. According to the heat recovery control by the control unit 40, the variable resistance value is adjusted so that the electric power P is suppressed not to exceed the upper limit as shown by an arrow in FIG. 16. That is, according to the heat recovery control by the control unit 40, the electric power P is controlled so that an excessive electric current does not flow into the load apparatus 32.

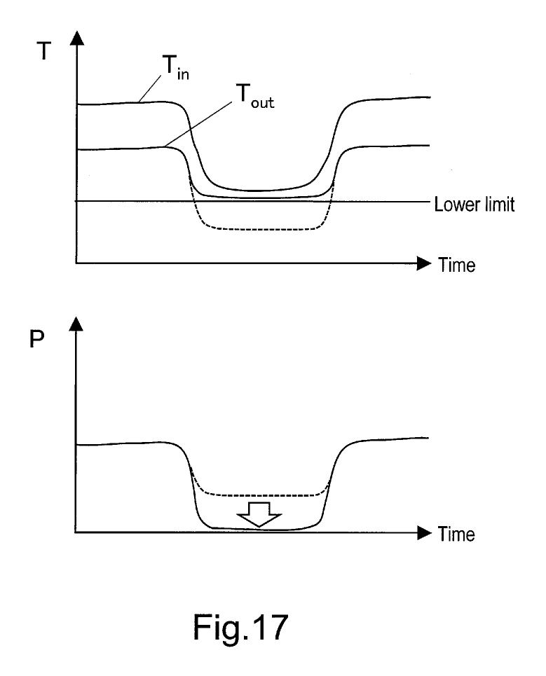

FIG. 17 shows an example of a relation between the temperature Tin at an upstream side of the thermoelectric transducing module 10 in the fluid passage 46, the electric power P generated by the thermoelectric transducing module 10, and the temperature Tout at a downstream side of the thermoelectric transducing module 10 in the fluid passage 46, which can be achieved by adjusting the variable resistance value. The ordinate axis T of the upper graph in FIG. 17 shows the temperature. The upper graph shows time variations of the upstream temperature Tin and the downstream temperature Tout. The ordinate axis P of the lower graph in FIG. 17 shows the electric power. The lower graph shows a time variation of the electric power P generated by the thermoelectric transducing module 10. The upper graph and the lower graph have a common time axis. In the case of the generation of electric power in the course of nature, the downstream temperature Tout of the fluid passage 46 may become lower than the lower limit temperature as shown by a dotted line because the heat that the exhaust heat recovery fluid has is consumed by the generation of electric power. According to the heat recovery control by the control unit 40, the variable resistance value is adjusted so that the electric power P is suppressed as shown by an arrow in FIG. 17 and thereby consumption of the heat that the exhaust heat recovery fluid has is suppressed so that the downstream temperature Tout of the fluid passage 46 does not become lower than the lower limit temperature. That is, according to the heat recovery control by the control unit 40, the electric power P is controlled so that a drop in the downstream temperature Tout of the fluid passage 46 is suppressed and the performance of the exhaust heat utilizing apparatus is secured.

### [Heat Recovery Control Program]

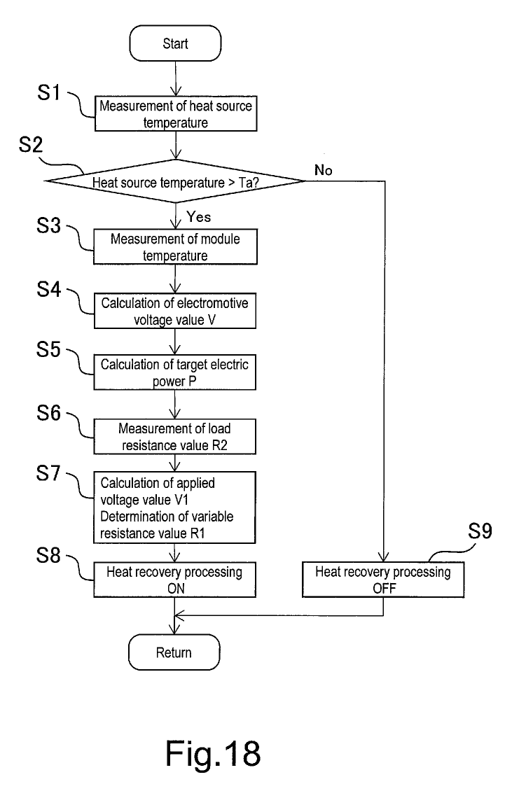

A heat recovery control program to execute the above described heat recovery control is stored in the memory 40a of the control unit 40. When an ignition is turned on, the control unit 40 reads the heat recovery control program from the memory 40a and makes the processor 40b execute it. FIG. 18 shows a flowchart indicating a procedure for the heat recovery control program. While the ignition is on, the control unit 40 executes the procedure shown in this flowchart repeatedly in a predetermined period.

In step S1, a heat source temperature that is a temperature of the exhaust heat recovery fluid flowing upstream of the thermoelectric transducing module 10 on the fluid passage 46 is measured by the heat source temperature sensor 44. Then, in step S2, the heat source temperature measured in step S1 is compared with the predetermined reference temperature Ta, and it is determined whether the heat source temperature is higher than the reference temperature Ta. For example, the reference temperature Ta is a lower limit temperature of a temperature range of the exhaust heat recovery fluid where the performance of the exhaust heat utilizing apparatus is secured. This lower limit temperature is determined by a target temperature or target temperature range of the exhaust heat utilizing apparatus.

When the heat source temperature is equal to or lower than the reference temperature Ta, step S9 is selected and heat recovery processing is turned off. That is, the electric circuit 30 is broken by switching off the current regulator 34, and thereby the generation of electric power by the thermoelectric transducing module 10 is stopped. As the result, the temperature of the exhaust heat recovery fluid flowing through the fluid passage 46 is prevented from further decreasing.

When the heat source temperature is higher than the reference temperature Ta, steps S3 to S8 are processed. In step S3, a module temperature that is a temperature of the thermoelectric transducing module 10 is measured by the module temperature sensor 42. Then, in step S4, an electromotive voltage value V of the thermoelectric transducing module 10 is calculated based on the module temperature measured in step S3. A relation between the module temperature and the electromotive voltage are defined in a map.

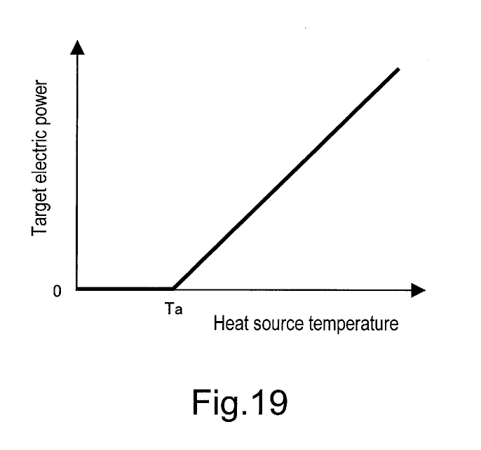

In step S5, a target electric power P is calculated. The target electric power P is a target value of the electric power that is taken out from the thermoelectric transducing module 10 (that is the electric power that the thermoelectric transducing module 10 is made to generate). Specifically, the control unit 40 calculates a heat amount recoverable from the exhaust heat recovery fluid flowing through the fluid passage 46 based on a difference between the heat source temperature and the reference temperature Ta. Then, the control unit 40 calculates the target electric power P based on the calculated recoverable heat amount. A map that associates the heat source temperature with the target electric power P is stored in the control unit 40. FIG. 19 shows an image of the map to determine the target electric power P based on the heat source temperature. As shown in FIG. 19, the control unit 40 sets the target electric power P to a larger value in order to recover more exhaust heat as the difference between the heat source temperature and the reference temperature Ta is larger, that is, the heat source temperature is higher. On the contrary, the control unit 40 sets the target electric power P to a smaller value in order to reduce the amount of heat absorbed by the thermoelectric transducing module 10 as the heat source temperature is lower. When the heat source temperature is lower than the reference temperature Ta, the control unit 40 sets the target electric power P to zero to stop the generation of electric power by the thermoelectric transducing module 10.

In step S6, the load resistance value R2 is measured. A method of measuring the load resistance value R2 is not limited. One method of measuring the load resistance value R2 is to measure a current flowing in the load apparatus 32 and a voltage applied to the load apparatus 32 and then calculate the load resistance value R2 from those measurements. Another method of measuring the load resistance value R2 is to measure a load resistance value every operating state of the load apparatus 32, make a map that associates the load resistance value with the operating state of the load apparatus 32 based on measurement results and then store the map in a memory.

In step S7, the applied voltage value V1 is calculated and the variable resistance value R1 is determined. The applied voltage value V1 is calculated using formula (1) based on the electromotive voltage value V calculated in step S4 and the target electric power P calculated in step S5. In formula (1), the internal resistance value Ri is a constant value and the internal resistance value Ri is measured or calculated beforehand. Then the variable resistance value R1 is determined using formula (2) based on the applied voltage value V1 and the load resistance value R2 measured in step S6.

In step S8, if the heat recovery processing was not executed at the previous routine, the execution of the heat recovery processing is started, and if the heat recovery processing was under execution at the previous routine, the execution of the heat recovery processing is continued. Specifically, the current regulator 34 is switched on or maintained to the on-state. Thus, an electric current flows in the electric circuit 30 and the generation of electric power by the thermoelectric transducing module 10 is performed. At this time, the current regulator 34 is operated according to the variable resistance value R1 determined in step S7.

By the above-described procedure being executed, the generation of electric power by the thermoelectric transducing module 10 is performed using the surplus exhaust heat while securing the exhaust heat amount required by the exhaust heat utilizing apparatus. That is, according to the heat recovery control by the control unit 40, the energy efficiency is improved by the exhaust heat being recovered while the influence of the generation of electric power by the thermoelectric transducing module 10 on the performance of the exhaust heat utilizing apparatus is suppressed.

### [Structure of Power Generator of Second Embodiment]

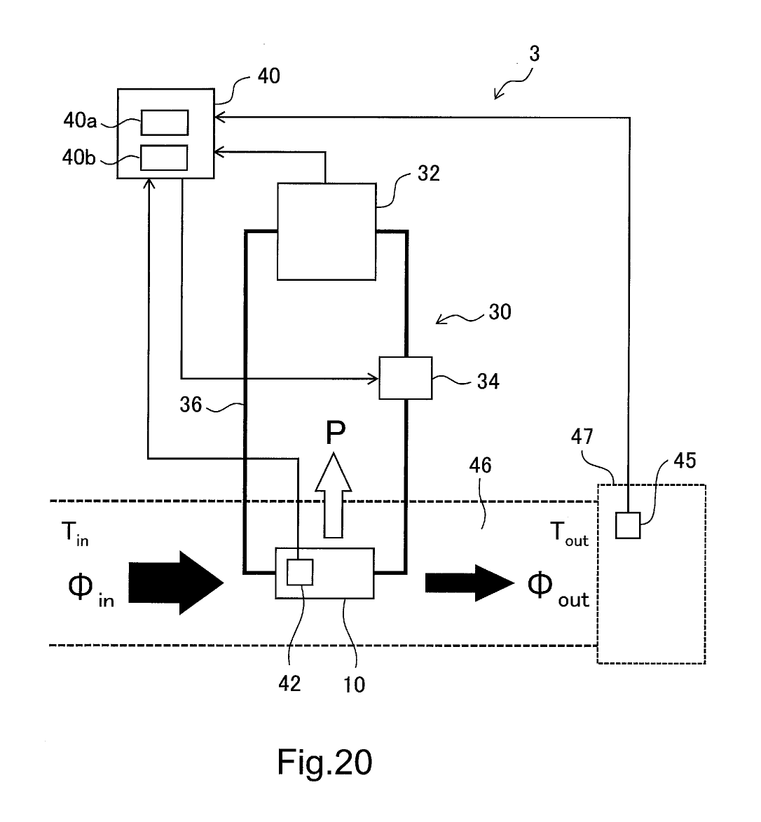

The following power generator, as well as the above-mentioned power generator 2 of the first embodiment, is a device to functionalize the thermoelectric transducing module 10. FIG. 20 shows a structure of the power generator 3 of a second embodiment. Among elements composing the power generator 3, an element common to the power generator 2 of the first embodiment shown in FIG. 11 is denoted by the same numeral reference.

As shown in FIG. 20, an exhaust heat utilizing apparatus 47 is placed downstream of the thermoelectric transducing module 10 on the fluid passage 46. The exhaust heat utilizing apparatus 47 is provided with a temperature sensor 45 to measure a temperature thereof. For example, if the fluid passage 46 is an exhaust passage of an internal combustion engine and the exhaust heat utilizing apparatus 47 is a catalyst to purify an exhaust gas, the temperature measured by the temperature sensor 45 is a catalyst temperature. The temperature sensor 45 is connected to the control unit 40 directly or through a communication network built in the vehicle. In the second embodiment, various sensors to acquire information associated with the heat recovery control include the temperature sensor 45. That is, a difference between the power generator 3 of the second embodiment and the power generator 2 of the first embodiment is in information that the control unit 40 of the thermoelectric transducing module 10 uses for generation control.

### [Heat Recovery Control Program]

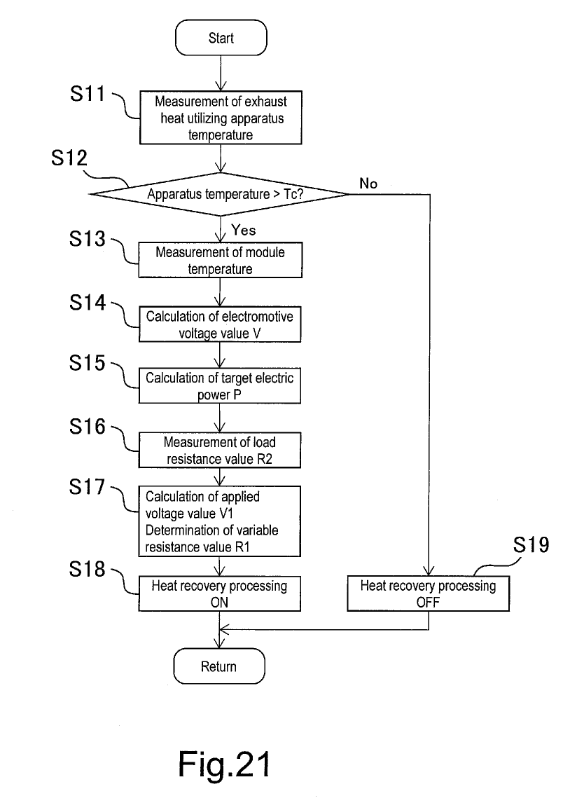

FIG. 21 shows a flowchart indicating a procedure for the heat recovery control program executed by the control unit 40 in the power generator 3 of the second embodiment. While the ignition is on, the control unit 40 executes the procedure shown in this flowchart repeatedly in a predetermined period.

In step S11, the temperature of the exhaust heat utilizing apparatus 47 is measured by the temperature sensor 45. Then, in step S12, the temperature (hereinafter, referred to as apparatus temperature) of the exhaust heat utilizing apparatus 47 measured in step S11 is compared with a predetermined reference temperature Tc. And, based on the comparison result, it is determined whether the apparatus temperature is higher than the reference temperature Tc. For example, the reference temperature Tc is a lower limit temperature of a temperature range where the exhaust heat utilizing apparatus 47 functions effectively. If the exhaust heat utilizing apparatus 47 is a catalyst that is placed on an exhaust passage of an internal combustion engine, the reference temperature Tc may be an active temperature of the catalyst.

When the apparatus temperature is equal to or lower than the reference temperature Tc, step S19 is selected and heat recovery processing is turned off. That is, the electric circuit 30 is broken by switching off the current regulator 34, and thereby the generation of electric power by the thermoelectric transducing module 10 is stopped. As the result, the temperature of the exhaust heat utilizing apparatus 47 is prevented from further decreasing than the reference temperature Tc.

When the apparatus temperature is higher than the reference temperature Tc, steps S13 to S18 are processed. Except step S15, the contents of the processing of steps S13 to S18 are the same as those of the processing of steps S3 to S8 of the flowchart shown in FIG. 11. Thus, only the processing of step S15 is described here.

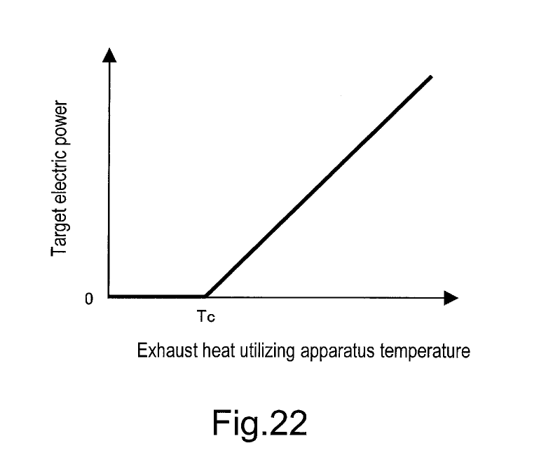

In step S15, a target electric power P is calculated. Specifically, the control unit 40 calculates a heat amount recoverable from the exhaust heat recovery fluid flowing through the fluid passage 46 based on a difference between the apparatus temperature and the reference temperature Tc. Then, the control unit 40 calculates the target electric power P based on the calculated recoverable heat amount. A map that associates the apparatus temperature with the target electric power P is stored in the control unit 40. FIG. 22 shows an image of the map to determine the target electric power P based on the temperature of the exhaust heat utilizing apparatus 47. As shown in FIG. 22, the control unit 40 sets the target electric power P to a larger value in order to recover more exhaust heat as the difference between the temperature of the exhaust heat utilizing apparatus 47 and the reference temperature Tc is larger, that is, the temperature of the exhaust heat utilizing apparatus 47 is higher. On the contrary, the control unit 40 sets the target electric power P to a smaller value in order to reduce the amount of heat absorbed by the thermoelectric transducing module 10 as the temperature of the exhaust heat utilizing apparatus 47 is lower. When the temperature of the exhaust heat utilizing apparatus 47 is lower than the reference temperature Tc, the control unit 40 sets the target electric power P to zero to stop the generation of electric power by the thermoelectric transducing module 10.

According to the heat recovery control by the power generator 3 of the second embodiment, the energy efficiency is improved by the exhaust heat being recovered while the influence of the generation of electric power by the thermoelectric transducing module 10 on the performance of the exhaust heat utilizing apparatus 47 is suppressed, as in the case of the first embodiment. Also, in comparison with the first embodiment, the second embodiment has an advantage to be able to execute the temperature control of the exhaust heat utilizing apparatus 47 accurately by controlling the generation of electric power by the thermoelectric transducing module 10 based on the actual temperature of the exhaust heat utilizing apparatus 47. On the other hand, the first embodiment has an advantage to be able to supply the exhaust heat recovery fluid temperature-regulated beforehand to the exhaust heat utilizing apparatus 47 by controlling the generation of electric power by the thermoelectric transducing module 10 based on the temperature of the exhaust heat recovery fluid at an upstream side of the exhaust heat utilizing apparatus 47.

### [Structure of Application Example of Power Generator]

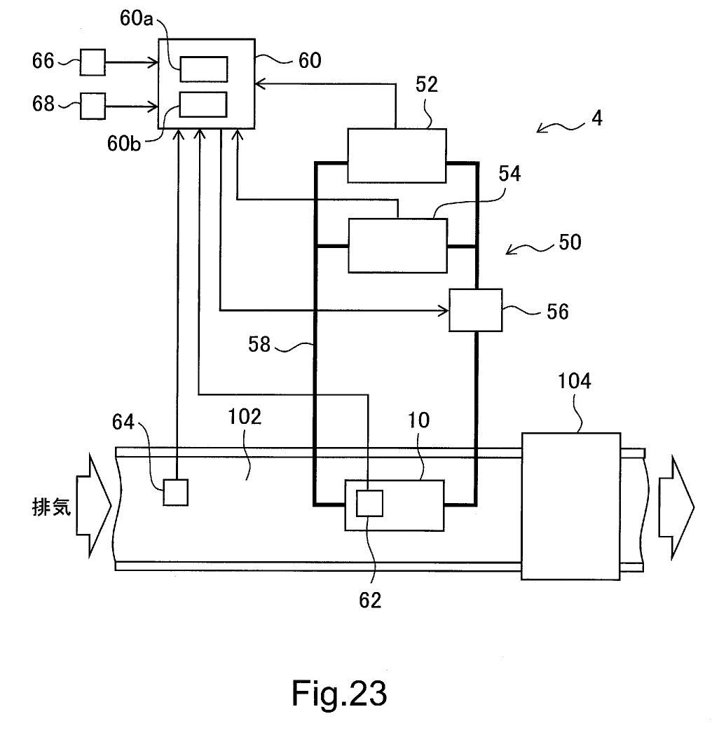

Next, an application example of the power generator of the above-mentioned embodiments will be described. The application example shown here is that of the first embodiment. FIG. 23 shows a structure of the application example of the power generator of the first embodiment. In the application example shown in FIG. 23, the power generator of the first embodiment is made as a power generator 4 recovering exhaust heat in an exhaust passage 102 of an internal combustion engine.

The power generator 4 of the application example comprises the thermoelectric transducing module 10 provided inside the exhaust passage 102. The thermoelectric transducing module 10 is placed upstream of the catalyst 104 in the exhaust passage 102. An electric component 52 that is a load apparatus and a battery 54 to save the electric power generated by the thermoelectric transducing module 10 are connected to the thermoelectric transducing module 10 in parallel by conducting wires 58. The electric components 52 includes various parts using electric power, for example, an air-conditioner, a light and a starter.

An electric circuit 50 comprising the thermoelectric transducing module 10, electric components 52 and battery 54 is further provided with a current regulator 56. The current regulator 56 is a device that varies an electric current applied to the electric circuit 50 from the thermoelectric transducing module 10. The current regulator 56 comprises a variable resistance to vary the electric current and a switch to turn on/off the electric current. The current regulator 56 is serially-connected to the electric components 52 and the battery 54.

The power generator 4 of the application example further comprises a control unit 60. The control unit 60 is an ECU comprising at least one memory 60a and at least one processor 60b. The memory 60a stores various data including a program and map for the heat recovery control. Functions for the heat recovery control are implemented into the control unit 60 by reading the program from the memory 60a and executing it by the processor 60b. The control unit 60 operates the resistance value of the variable resistance of the current regulator 56, and thereby varies the electric current value to control the electric power generated by the thermoelectric transducing module 10.

Various sensors to acquire information associated with the heat recovery control are connected to the control unit 60 directly or through a communication network built in the vehicle. The sensors connected to the control unit 60 include a module temperature sensor 62, an exhaust temperature sensor 64, a water temperature sensor 66 and an oil temperature sensor. The module temperature sensor 62 is a sensor that is provided inside the thermoelectric transducing module 10 and measures a temperature of the thermoelectric transducing module 10. The exhaust temperature sensor 64 is a sensor that is placed upstream of the thermoelectric transducing module 10 on the exhaust passage 102 and measures a temperature of the exhaust gas that is a heat source. The water temperature sensor 66 is a sensor that measures a temperature of the coolant that has passed through the internal combustion engine. The oil temperature sensor 68 is a sensor that measures a temperature of the oil that circulates through the internal combustion engine. Furthermore, a voltage sensor not shown is attached to the battery 54 and is connected to the control unit 60. The control unit 60 calculates a state of charge (SOC) of the battery 54 from the open voltage of the battery 54 that is measured by the voltage sensor.

### [Heat Recovery Control Program of Application Example]

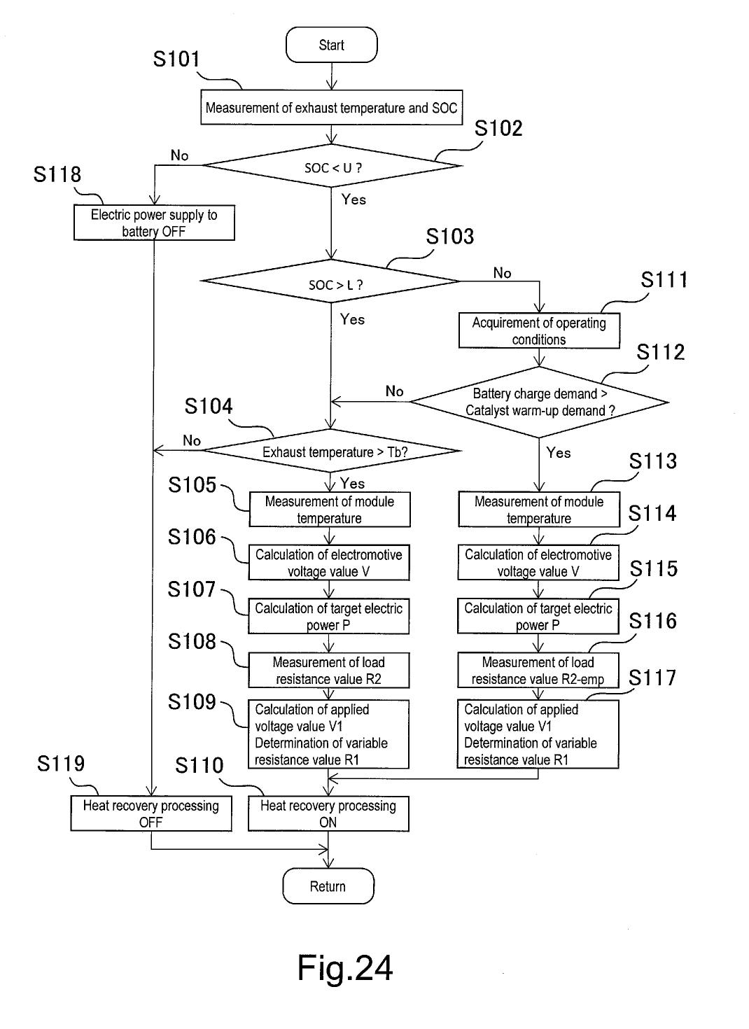

A heat recovery control program to execute the above described heat recovery control is stored in the memory 60a of the control unit 60. When an ignition is turned on, the control unit 60 reads the heat recovery control program from the memory 60a and makes the processor 60b execute it. FIG. 24 shows a flowchart indicating a procedure for the heat recovery control program that is executed by the control unit 60. While the ignition is on, the control unit 60 executes the procedure shown in this flowchart repeatedly in a predetermined period.

In step S101, an exhaust temperature and a SOC are measured by respective sensors. Then, in step S102, the SOC measured in step S101 is compared with an upper limit U. And, based on the comparison result, it is determined whether the SOC is lower than the upper limit U. The upper limit U of the SOC is set for preventing the battery 54 from being overcharged.

When the SOC is equal to or more than the upper limit U, step S118 is selected and supplying electric power to the battery 54 is turned off to prevent the battery 54 from being overcharged. Also, step S119 is selected successively. In step S119, the electric circuit 50 is broken by switching off the current regulator 56, and thereby the generation of electric power by the thermoelectric transducing module 10 is stopped. However, stopping the heat recovery processing is optional. The heat recovery processing may be continued whereas supplying electric power to the battery 54 is stopped.

When the SOC is less than the upper limit U, a determination of step S103 is performed. In step S103, the SOC measured in step S101 is compared with the lower limit L. And, based on the comparison result, it is determined whether the SOC is more than the lower limit L. The lower limit L of the SOC is set for preventing the battery 54 from being over-discharged.

When the SOC is more than the lower limit L, that is, when the battery 54 is not in an overcharge state nor an over-discharge state, a determination of step S104 is performed. In step S104, the exhaust temperature measured in step S101 is compared with a reference temperature Tb. And, based on the comparison result, it is determined whether the exhaust temperature is higher than the reference temperature Tb. A catalyst 104 is placed downstream of the thermoelectric transducing module 10 on the exhaust passage 102. The catalyst 104 has a temperature range where the purification performance thereof is maintained. If a target temperature of the catalyst 104 is in the temperature range where the purification performance of the catalyst 104 is maintained, the reference temperature Tb is a lower limit of the exhaust temperature determined from the target temperature of the catalyst 104.

When the exhaust temperature is equal to or lower than the reference temperature Tb, step S119 is selected and heat recovery processing is turned off. That is, the electric power generated by the thermoelectric transducing module 10 is controlled so that, when the temperature of the catalyst 104 is low, the amount of heat absorbed by the thermoelectric transducing module 10 decreases in comparison with the case that the temperature of the catalyst 104 is high. According to this, a drop in the temperature of the exhaust gas flowing into the catalyst 104 is suppressed, and thereby a drop in the purification performance of the catalyst 104 is suppressed.

When the exhaust temperature is higher than the reference temperature Tb, steps S105 to S110 are processed. In step S105, a module temperature that is a temperature of the thermoelectric transducing module 10 is measured by the module temperature sensor 62. Then, in step S106, an electromotive voltage value V of the thermoelectric transducing module 10 is calculated based on the module temperature measured in step S105.

In step S107, a target electric power P is calculated. The control unit 60 calculates a heat amount recoverable from the exhaust gas flowing through the exhaust passage 102 based on a difference between the exhaust temperature and the reference temperature Tb. The control unit 60 calculates the target electric power P based on the calculated recoverable heat amount. A map that associates the exhaust temperature with the target electric power P is used for a calculation of the target electric power P. The relation between the exhaust temperature and the target electric power defined in this map is shown in FIG. 19. However, in FIG. 19, the heat source temperature of the abscissa axis is replaced with the exhaust temperature, and the reference temperature Ta is replaced with the reference temperature Tb. The exhaust temperature relates to a temperature of the catalyst 104. It can be estimated that, when the exhaust temperature is high, the temperature of the catalyst 104 is also high and, when the exhaust temperature is low, the temperature of the catalyst 104 is also low. Thus, according to the method of calculating the target electric power that is performed in this step, when the temperature of the catalyst 104 is estimated to be low, the electric power generated by the thermoelectric transducing module 10 is suppressed in comparison with the case that the temperature of the catalyst 104 is estimated to be high.

In step S108, a load resistance value R2 is measured. However, in the case of the circuit shown in FIG. 23, the load resistance value R2 means a resistance value of a circuit element (load resistance) consisting of the electric component 52 and the battery 54. The load resistance value R2 depends on the operating state of the electric component 52 and the SOC of the battery 54. Thus, the load resistance value R2 may be calculated from the current operating state of the electric component 52 and the current SOC of the battery 54 with use of a map that associates the load resistance value with the operating state of the electric component 52 and the SOC of the battery 54.

In step S109, an applied voltage value V1 is calculated using formula (1) based on the target electric power P calculated in step S107 and the electromotive voltage value V calculated in step S106. Also, a variable resistance value R1 is determined using formula (2) based on the load resistance value R2 measured in step S108 and the applied voltage value V1.

In step S110, the current regulator 56 is switched on. Thus, an electric current flows in the electric circuit 50 and the generation of electric power by the thermoelectric transducing module 10 is performed. Also, the current regulator 56 is operated according to the variable resistance value R1 determined in step S109.

By the above-described procedure being executed, the generation of electric power by the thermoelectric transducing module 10 is performed using the surplus exhaust heat while securing the exhaust heat amount necessary for a warm-up of the catalyst 104. That is, the energy efficiency is improved by the exhaust heat being recovered while the influence of the generation of electric power by the thermoelectric transducing module 10 on the purification performance of the catalyst 104 is suppressed.

On the other hand, when the result of the determination of step S103 is that the SOC is equal to or less than the lower limit L, it is determined that the battery 54 is in or approaching an over-discharge state. In this case, at first, operating conditions of the vehicle are acquired in step S111. Then, in step S112, it is determined based on the operating conditions acquired in step S111 which demand is given priority to, a demand to warm-up the catalyst 104 or a demand to charge the battery 54. The determination method of step S112 may be to calculate a parameter corresponding to a difference between the current SOC of the battery 54 and a target SOC thereof and a parameter corresponding to a difference between the current temperature of the catalyst 104a and the target temperature thereof and to compare these two parameters. When the demand to warm-up the catalyst 104 is given priority to, step S104 is selected and the exhaust temperature is compared with the reference temperature Tb.

However, when the demand to charge the battery 54 is given priority to, steps S113 to S117 and step S110 are processed regardless of the exhaust temperature.

The processing of steps S113 to S117 corresponds to the processing of steps S105 to S109 described previously. In step S113, a module temperature is measured by the module temperature sensor 62. In step S114, an electromotive voltage value V of the thermoelectric transducing module 10 is calculated based on the module temperature measured in step S113. In step S115, a target electric power P is calculated. In step S116, a load resistance value R2-emp is measured. Note that the load resistance value R2-emp measured in step S116 is a load resistance value in a state that the battery 54 is approximately empty. In the map that associates the load resistance value with the operating state of the electric component 52, the SOC of the battery 54 is also associated with the load resistance value. In step S117, an applied voltage value V1 is calculated, and further a variable resistance value R1 is determined.

Step S110 is processed after step S117. In step S110, the current regulator 56 is switched on. Thus, an electric current flows in the electric circuit 50 and the generation of electric power by the thermoelectric transducing module 10 is performed. Also, the current regulator 56 is operated according to the variable resistance value R1 determined in step S117.

By the above-described procedure being executed, the battery 54 is charged by the electric power generated by the thermoelectric transducing module 10 and is prevented from being over-discharged.

### [Other Application Example]

In the above application example, the thermoelectric transducing module 10 is placed on the exhaust passage 102. However, as explained in the section [Application of Thermoelectric Transducing Module], the thermoelectric transducing module 10 can be placed anywhere as long as exhaust heat of the internal combustion engine is transmitted to. For example, when the thermoelectric transducing module 10 is placed on a coolant circulation system, the heat recovery control program shown in FIG. 21 can be applied to the heat recovery control using the thermoelectric transducing module 10. Specifically, in step S101, a cooling water temperature is measured in substitution for an exhaust temperature, and in step S104, it is determined whether the cooling water temperature is higher than a reference temperature Tc. The reference temperature Tc of this case is a coolant temperature showing that a warm-up of the internal combustion engine is completed. Also, in step S112, it is determined which demand is given priority to, a demand to warm-up the internal combustion engine or a demand to charge the battery 54. The heat recovery control program shown in FIG. 21 can also be applied to the heat recovery control using the thermoelectric transducing module 10 placed on an oil circulation system.

Further, the above application example can be modified as an application example of the second embodiment 2. In the modification, a catalyst temperature sensor is provided to the catalyst 104 in substitution for the exhaust temperature sensor 64, and a heat recovery control program is configured to determine a target electric power based on a catalyst temperature measured by the catalyst temperature sensor.

What is claimed is:

1. A power generator for a vehicle equipped with a heat generating apparatus that generates heat during operation, the power generator comprising;
a thermoelectric transducing module that is placed on a part where exhaust heat generated from the heat generating apparatus is transmitted, and comprises a semiconductor single crystal that has an n-type semiconductor part, a p-type semiconductor part and an intrinsic semiconductor part located between the n-type semiconductor part and the p-type semiconductor, the intrinsic semiconductor part having a narrower band gap than band gaps of the n-type semiconductor part and the p-type semiconductor part;
a load apparatus composing an electric circuit in cooperation with the thermoelectric transducing module;
a current regulator that is installed in the electric circuit and varies an electric current that is applied to the electric circuit from the thermoelectric transducing module; and
a control unit that operates the current regulator to control electric power generated by the thermoelectric transducing module.

2. The power generator for a vehicle according to claim 1,
wherein the vehicle is further equipped with a fluid passage where an exhaust heat recovery fluid that recovers exhaust heat of the heat generating apparatus flows and an exhaust heat utilizing apparatus that receives an exhaust heat supply from the exhaust heat recovery fluid flowing through the fluid passage,
wherein the thermoelectric transducing module is placed upstream of the exhaust heat utilizing apparatus on the fluid passage, and
wherein the control unit is configured to control the electric power generated by the thermoelectric transducing module according to a temperature of the exhaust heat recovery fluid flowing through the fluid passage or a temperature of the exhaust heat utilizing apparatus.

3. The power generator for a vehicle according to claim 2,
wherein the control unit is configured to control the electric power generated by the thermoelectric transducing module so that, when the temperature of the exhaust heat recovery fluid flowing through the fluid passage is low, an amount of heat absorbed by the thermoelectric transducing module decreases in comparison with a case that the temperature of the exhaust heat recovery fluid flowing through the fluid passage is high.

4. The power generator for a vehicle according to claim 3,
wherein the control unit is configured to stop generation of electric power by the thermoelectric transducing module when the temperature of the exhaust heat recovery fluid flowing through the fluid passage is equal to or lower than a predetermined temperature.

5. The power generator for a vehicle according to claim 2,
wherein the control unit is configured to control the electric power generated by the thermoelectric transducing module so that, when the temperature of the exhaust heat utilizing apparatus is low, an amount of heat absorbed by the thermoelectric transducing module decreases in comparison with a case that the temperature of the exhaust heat utilizing apparatus is high.

6. The power generator for a vehicle according to claim 5,
wherein the control unit is configured to stop generation of electric power by the thermoelectric transducing module when the temperature of the exhaust heat utilizing apparatus is equal to or lower than a predetermined temperature.

7. The power generator for a vehicle according to claim 2,
wherein the heat generating apparatus is an internal combustion engine, the fluid passage is an exhaust passage where an exhaust gas from the internal combustion engine flows and the exhaust heat utilizing apparatus is a catalyst that purifies the exhaust gas.

8. The power generator for a vehicle according to claim 1,
wherein the control unit is configured to vary a manipulated variable of the current regulator according to the temperature of the thermoelectric transducing module.

9. The power generator for a vehicle according to claim 1,
wherein the load apparatus is an apparatus that varies a resistance value of the electric circuit depending on its own operating state, and
wherein the control unit is configured to vary a manipulated variable of the current regulator depending on the operating state of the load apparatus.

10. The power generator for a vehicle according to claim 1,
wherein the heat generating apparatus is an internal combustion engine,
wherein the thermoelectric transducing module is placed upstream of a catalyst on an exhaust passage where an exhaust gas from the internal combustion engine flows, and
wherein the control unit is configured to control the electric power generated by the thermoelectric transducing module so that, when a temperature of the catalyst is low or is estimated to be low, an amount of heat absorbed by the thermoelectric transducing module decreases in comparison with a case that the temperature of the catalyst is high or is estimated to be high.

11. The power generator for a vehicle according to claim 1, further comprising a battery connected to the electric circuit,
wherein the control unit is configured to control the electric power generated by the thermoelectric transducing module based on a state of charge of the battery.
